(19) United States
(12) Patent Application Publication
(10) Pub. No.: US 2026/0161854 A1
(43) Pub. Date: Jun. 11, 2026

(54) ARTIFICIAL INTELLIGENCE METHOD FOR GENERATING LIGHTING EFFECTS OF AND ELECTRONIC DEVICE USING THE SAME

(71) Applicant: Acer Incorporated, New Taipei City (TW)

(72) Inventors: Kuan-Ju CHEN, New Taipei City (TW); Liang-Chi CHEN, New Taipei City (TW)

(73) Assignee: Acer Incorporated, New Taipei City (TW)

(21) Appl. No.: 19/340,136

(22) Filed: Sep. 25, 2025

(30) Foreign Application Priority Data
Dec. 11, 2024 (TW) 113148134

(51) Int. Cl. G06F 30/27

(52) U.S. Cl. CPC G06F 30/27

(57) ABSTRACT

An artificial intelligence method for generating lighting effects of and an electronic device using the same are provided. The artificial intelligence method for generating the lighting effects is used to display a lighting effect pattern corresponding to a screen image on a lighting effect device. The artificial intelligence method for generating the lighting effects includes the following steps. An initialization procedure is performed to obtain a content and a dimension of a data format of a model inputting tensor and a model outputting tensor of an artificial intelligence model. An execution procedure is performed to adjust a frame tensor of the screen image according to the content and the dimension of the data format of the model inputting tensor, and to adjust an inference result of the artificial intelligence model according to the content and the dimension of the data format of the model outputting tensor.

This application claims the benefit of Taiwan application Serial No. 113148134, filed Dec. 11, 2024, the disclosure of which is incorporated by reference herein in its entirety.

### TECHNICAL FIELD

The disclosure relates to a lighting effects generating method and an electronic device using the same, and particularly to an artificial intelligence method for generating lighting effects of and an electronic device using the same.

### BACKGROUND

Some laptops have several key light sources installed under the keyboard to provide backlighting for the keys. These key light sources could help users identify the keys in the dark and could also be used to create different lighting effects.

A key light source could be used as a lighting effect device to provide static lighting effects or keyboard lighting effects. However, these lighting effects are only preset patterns and cannot be mapped to the screen image.

In addition, since the screen image changes rapidly, when the central processing unit is overloaded, it may not be possible to calculate the lighting effect pattern in real time. Therefore, researchers are working to develop a technology that can calculate the lighting effect pattern in real time according to the screen image.

### SUMMARY

The present disclosure relates to an artificial intelligence method for generating lighting effects and an electronic device using the same. The electronic device utilizes a neural network processing unit or a graphics processing unit unified with CUDA to perform the artificial intelligence method for generating the lighting effects. In scenarios like gaming and multimedia creation, the central processing unit and the graphics processing unit are nearly fully loaded. However, the unified CUDA architecture of the neural network processing unit and the graphics processing unit still has sufficient computing power. Furthermore, this unified CUDA architecture is particularly well-suited for artificial intelligence (AI) computing. Therefore, this disclosure utilizes the computing resources of the CUDA in the neural network processing unit and the graphics processing unit to execute the artificial intelligence method for generating the lighting effects. This method allows for real-time calculation of lighting effect patterns in response to rapid changes in the screen image.

According to one embodiment, an artificial intelligence method for generating lighting effects is provided. The artificial intelligence method is used to display a lighting effect pattern corresponding to a screen image on a lighting effect device. The artificial intelligence method for generating the lighting effects includes the following steps. An initialization procedure is performed to obtain a content and a dimension of a data format of a model inputting tensor and a model outputting tensor of an artificial intelligence model. An execution procedure is performed to adjust a frame tensor of the screen image according to the content and the dimension of the data format of the model inputting tensor, and to adjust an inference result of the artificial intelligence model according to the content and the dimension of the data format of the model outputting tensor.

According to another embodiment, an electronic device is provided. The electronic device includes a display unit, a lighting effect device, an operating system kernel unit, a neural network processing unit (NPU) and a graphic process unit (GPU). The display unit is used to display a screen image. The lighting effect device is used to display a lighting effect pattern corresponding to the screen image. The operating system kernel unit is connected to the display unit and the lighting effect device. The neural network processing unit (NPU) is connected to the operating system kernel unit. The graphic process unit (GPU) is connected to the operating system kernel unit. The graphic process unit includes a Compute Unified Device Architecture (CUDA). The electronic device is loaded with a program to execute an artificial intelligence method for generating lighting effects. The artificial intelligence method for generating the lighting effects incudes the following steps. The operating system kernel unit performs an initialization procedure to obtain a content and a dimension of a data format of a model inputting tensor and a model outputting tensor of an artificial intelligence model. The CUDA of the neural network processing unit or the graphic process unit performs an execution procedure, to adjust a frame tensor of the screen image according to the content and the dimension of the data format of the model inputting tensor, and to adjust an inference result of the artificial intelligence model according to the content and the dimension of the data format of the model outputting tensor.

### BRIEF DESCRIPTION OF THE DRAWINGS

FIG. 1 illustrates an electronic device according to an embodiment of the present disclosure.

FIG. 2 illustrates a schematic diagram of an artificial intelligence method for generating lighting effects according to one embodiment of the present disclosure.

FIG. 3 illustrates a computing resource allocation for the artificial intelligence method for generating the lighting effects according to an embodiment of the present disclosure.

FIG. 4 illustrates a flowchart of an initialization procedure of the artificial intelligence method for generating the lighting effects according to one embodiment of the present disclosure.

FIG. 5 illustrates a schematic diagram of a keyboard according to an embodiment of the present disclosure.

FIG. 6 illustrates a light source distribution map of a light source of a lighting effect device according to an embodiment of the present disclosure.

FIG. 7 illustrates a lighting effect matrix according to one embodiment of the present disclosure.

FIG. 8 illustrates steps S122 through S124.

FIGS. 9A to 9B illustrate a flow chart of an execution procedure of the artificial intelligence method for generating the lighting effects according to one embodiment of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The technical terms used in this specification refer to the idioms in this technical field. If there are explanations or definitions for some terms in this specification, the explanation or definition of this part of the terms shall prevail. Each embodiment of the present disclosure has one or more technical features. To the extent possible, a person with ordinary skill in the art may selectively implement some or all of the technical features in any embodiment, or selectively combine some or all of the technical features in these embodiments.

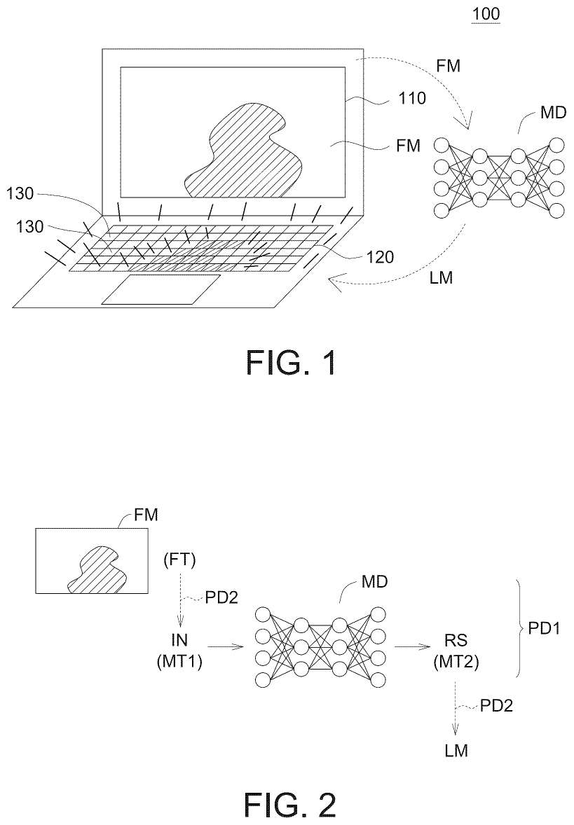

Please refer to FIG. 1, which illustrates an electronic device 100 according to an embodiment of the present disclosure. The electronic device 100 is, for example, a notebook computer, a smartphone, or a gaming device. In the present disclosure, a lighting effect device 130 is disposed below a keyboard 120 of the electronic device 100. The lighting effect device 130 could produce a lighting effect pattern LM corresponding to a screen image FM of a display unit 110.

In the present disclosure, a lighting effect pattern LM could be inferred according to the screen image FM of the display unit 110 by an artificial intelligence model MD. Please refer to FIG. 2, which illustrates a schematic diagram of the artificial intelligence method for generating the lighting effects according to one embodiment of the present disclosure. The lighting effect pattern LM could be inferred according to the screen image FM by the artificial intelligence model MD. However, the input data IN of the artificial intelligence model MD has a specific model inputting tensor MT1. A frame tensor FT of the screen image FM may not necessarily match this model inputting tensor MT1.

The inference result RS of the artificial intelligence model MD has a specific model outputting tensor MT2. However, the inference result RS of the artificial intelligence model MD may not conform to the format of the lighting effect pattern LM. Therefore, this disclosure proposes a processing architecture that allows artificial intelligence model MD to infer the lighting effect pattern LM according to the screen image FM.

As shown in FIG. 2, the artificial intelligence method for generating the lighting effects proposed in this disclosure includes an initialization procedure PD1 and an execution procedure PD2. The initialization procedure PD1 is used to obtain the data format and the dimensions of the model inputting tensor MT1 and the model outputting tensor MT2 of the artificial intelligence model MD.

The execution procedure PD2 adjusts the frame tensor FT of the screen image FM according to the data format and the dimensions of the model inputting tensor MT1. It also adjusts the inference result RS to conform to the format of the lighting effect pattern LM according to the data format and dimensions of the model outputting tensor MT2.

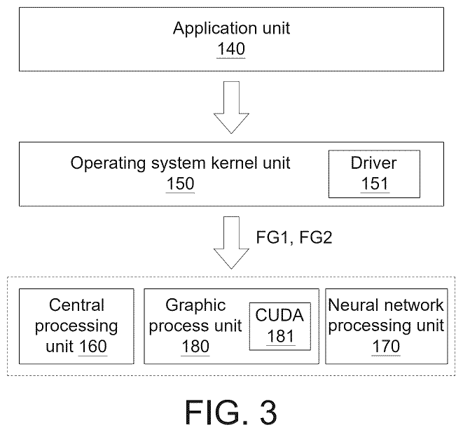

Please refer to FIG. 3, which illustrates the computing resource allocation for the artificial intelligence method for generating the lighting effects according to an embodiment of the present disclosure. The computing resource architecture of the electronic device 100 includes, for example, an application unit 140, an operating system kernel unit 150, a central processing unit (CPU) 160, a neural network processing unit (NPU) 170, and a graphics processing unit (GPU) 180. The operating system kernel unit 150 includes various drivers 151. The graphics processing unit 180 includes at least a Compute Unified Device Architecture (CUDA) 181.

In the present disclosure, the operating system kernel unit 150 is used to perform the initialization procedure PD1; and the CUDA 181 of the neural network processing unit 170 or the graphic process unit 180 is used to perform the execution procedure PD2. In situations like gaming and multimedia creation, the central processing unit 160 and the graphics processing unit 180 are nearly fully loaded, but the CUDA 181 of the neural network processing unit 170 or the graphics processing unit 180 still have enough computing resource. The CUDA 181 is particularly well-suited for artificial intelligence computing. Therefore, the present disclosure utilizes computing resources such as the CUDA 181 of the neural network processing unit 170 and the graphics processing unit 180 to execute the artificial intelligence method for generating the lighting effects, thereby instantly computing the lighting effect pattern LM in response to rapid changes in the screen image FM.

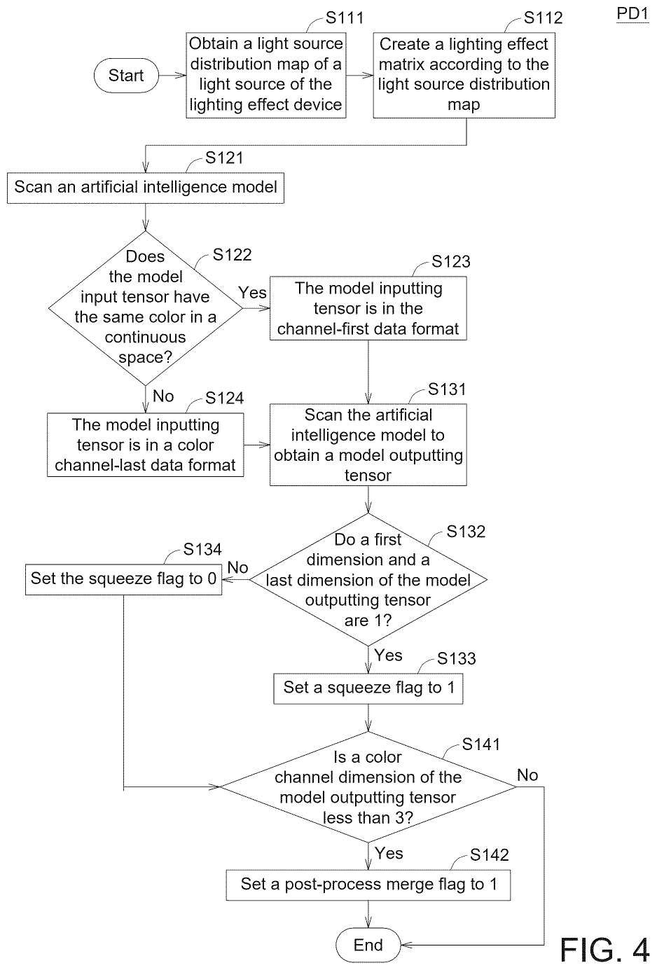

Please refer to FIG. 4, which illustrates a flowchart of the initialization procedure PD1 of the artificial intelligence method for generating the lighting effects according to one embodiment of the present disclosure. The initialization procedure PD1 includes steps S111 to S112, S121 to S124, S131 to S134, and S141 to S142.

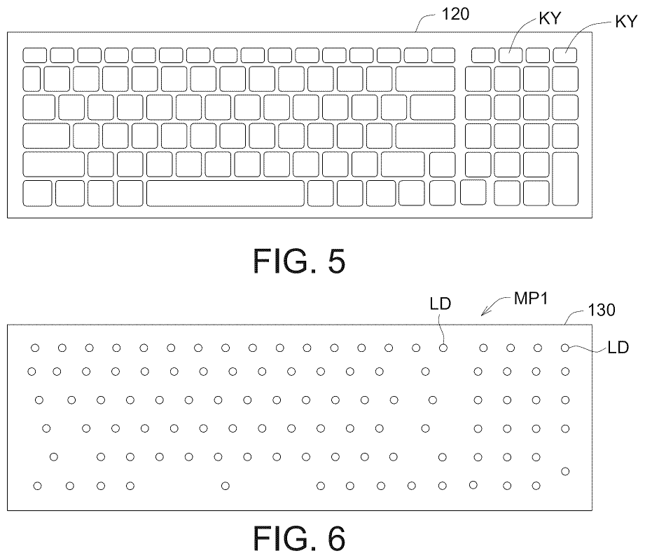

Please refer to FIGS. 5 to 6. FIG. 5 illustrates a schematic diagram of the keyboard 120 according to an embodiment of the present disclosure, and FIG. 6 illustrates a light source distribution map MP1 of the light source LD of the lighting effect device 130 according to an embodiment of the present disclosure. In the step S111, as shown in FIGS. 5 to 6, the light source distribution map MP1 of the light source LD of the lighting effect device 130 is obtained. The keys KY of the keyboard 120 are not arranged in a uniform pattern, nor are the light sources LD of the lighting effect device 130 located below the keyboard 120. In the light source distribution map MP1, most keys KY correspond to the light source LD. The light source LD is, for example, an LED lamp.

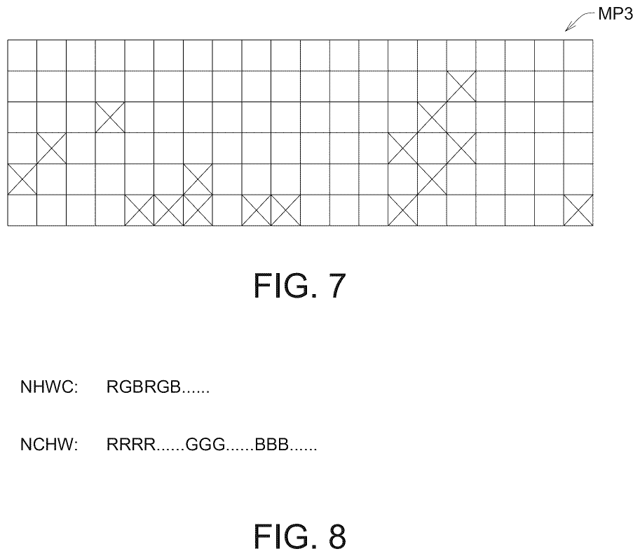

Next, please refer to FIG. 7, which illustrates a lighting effect matrix MP3 according to one embodiment of the present disclosure. In the step S112, as shown in FIG. 7, the lighting effect matrix MP3 is created according to the light source distribution map MP1. The lighting effect matrix MP3 maps out illuminable blank areas and non-illuminable crossed-out areas. These illuminable blank areas are used to map the aforementioned lighting effect pattern LM.

Then, in the step S121, as shown in FIG. 2, the artificial intelligence model MD is scanned to obtain the model inputting tensor MT1.

Next, please refer to FIG. 8, which illustrates steps S122 through S124. In the S122, whether the model input tensor MT1 has the same color in a continuous space is determined. As shown in FIG. 8, if the model input tensor MT1 has the same color in a continuous space (e.g., red R, red R, red R., . . . , green G, green G, green G, green G, . . . , blue B, blue B, blue B, . . . ), the process proceeds to the step S123. If the model input tensor MT1 does not have the same color in a continuous space (e.g., red R, green G, blue B, red R, green G, blue B, . . . ), the process proceeds to the step S124.

In the step S123, as shown in FIG. 8, the model inputting tensor MT1 is deemed to be in the channel-first data format (e.g., NCHW data format).

In the step S124, as shown in FIG. 8, the model inputting tensor MT1 is deemed to be in a color channel-last data format (e.g., NHWC data format).

Then, in the step S131, as shown in FIG. 2, the artificial intelligence model MD is scanned to obtain the model outputting tensor MT2.

Next, in the step S132, as shown in FIG. 2, whether the first dimension and the last dimension of the model outputting tensor MT2 is 1 is determined. If both of the first dimension and the last dimension of the model outputting tensor MT2 are 1, the process proceeds to the step S133. If neither the first dimension or the last dimension of the model outputting tensor MT2 is 1, the process proceeds to the step S134.

In the step S133, as shown in FIG. 3, a squeeze flag FG1 is set to 1.

In the step S134, as shown in FIG. 3, the squeeze flag FG1 is set to 0. The squeeze flag FG1 is used for the execution procedure PD2 to determine whether the dimension reduction is required.

Next, in the step S141, as shown in FIG. 2, whether the color channel dimension of the model outputting tensor MT2 is less than 3 is determined. Generally, the inputting data IN received by the artificial intelligence model MD is color data, and the color channel dimension of the model outputting tensor MT2 is 3. In some cases, the inputting data IN (shown in FIG. 2) received by the artificial intelligence model MD may be monochrome data, with the color channel dimension of the model outputting tensor MT2 being 1. Alternatively, the color channel dimension of the model outputting tensor MT2 may have other values. If the color channel dimension of the model outputting tensor MT2 is less than 3, the process proceeds to the step S142. If the color channel dimension of the model outputting tensor MT2 is not less than 3, the process ends.

In the step S142, as shown in FIG. 3, the post-process merge flag FG2 is set to 1. The post-process merge flag FG2 is used for the execution procedure PD2 to determine whether data merging is required.

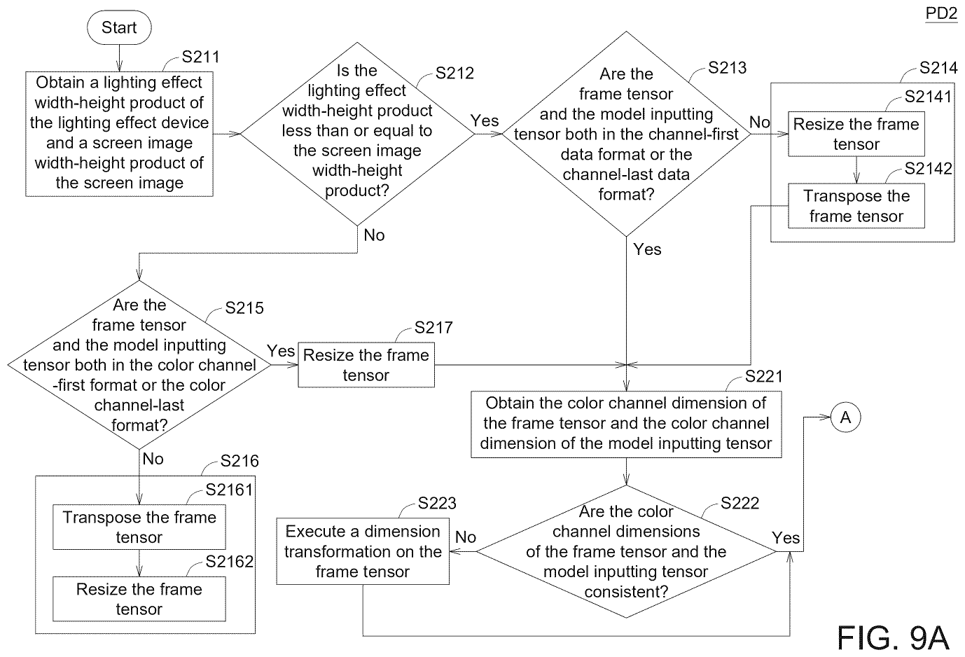

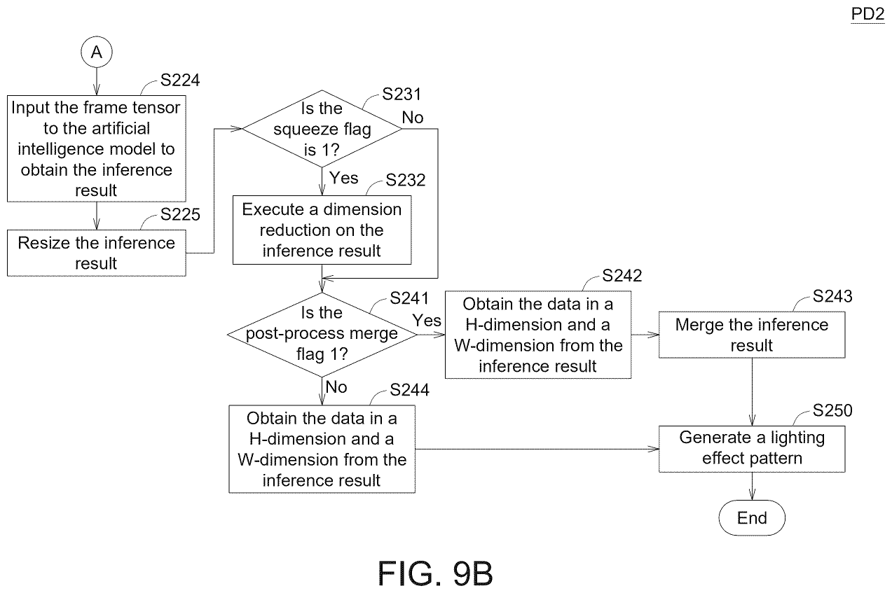

Please refer to FIGS. 9A to 9B, which illustrate a flow chart of the execution procedure PD2 of the artificial intelligence method for generating the lighting effects according to one embodiment of the present disclosure. The execution procedure PD2 of the artificial intelligence method for generating the lighting effects includes steps S211 to S217, S221 to S225, S231 to S232, S241 to S244, and S250.

In the step S211, as shown in FIG. 1, the lighting effect width-height product of the lighting effect device 130 and the screen image width-height product of the screen image FM are obtained.

Next, in the step S212, whether the lighting effect width-height product is less than or equal to the screen image width-height product is determined. If the lighting effect width-height product is less than or equal to the screen image width-height product, the process proceeds to the step S213. If the lighting effect width-height product is larger than the screen image width-height product, the process proceeds to the step S215.

In the step S213, as shown in FIG. 2, whether the frame tensor FT and the model inputting tensor MT1 are both in the channel-first data format or the channel-last data format is determined. If neither the frame tensor FT nor the model inputting tensor MT1 is in the color channel-first data format nor the color channel-last data format, the process proceeds to the step S214. If both the frame tensor FT and the model inputting tensor MT1 are in the color channel-first data format or the color channel-last data format, the process proceeds to the step S221.

The step S214 includes step S2141 and step S2142.

In the step S2141, as shown in FIG. 2, the frame tensor FT is resized so that the size of the frame tensor FT is consistent with the size of the model inputting tensor MT1.

In the step S2142, as shown in FIG. 2, the frame tensor FT is transposed to align its data format with the model input tensor MT1. In other words, the step S214 first reduces the size of the frame tensor FT and then transposes it to prevent distortion.

In the step S215, as shown in FIG. 2, whether the frame tensor FT and the model inputting tensor MT1 are both in the color channel-first format or the color channel-last format is determined. If neither the frame tensor FT nor the model inputting tensor MT1 is in the color channel-first format, the process proceeds to the step S216. If both of the frame tensor FT and the model inputting tensor MT1 are in the color channel-last format, the process proceeds to the step S217.

The step S216 includes step S2161 and step S2162.

In the step S2161, as shown in FIG. 2, the frame tensor FT is transposed so that the data format of the frame tensor FT is consistent with that of the model inputting tensor MT1.

In the step S2162, as shown in FIG. 2, the frame tensor FT is resized to match the size of the model input tensor MT1. In other words, the step S216 first transposes the frame tensor FT to prevent distortion and then scales it up.

Next, in the step S217, as shown in FIG. 2, the frame tensor FT is resized so that the size of the frame tensor FT is consistent with that of the model inputting tensor MT1.

Then, in the step S221, as shown in FIG. 2, the color channel dimension of the frame tensor FT and the color channel dimension of the model inputting tensor MT1 are obtained.

Next, in the step S222, as shown in FIG. 2, whether the color channel dimensions of the frame tensor FT and the model inputting tensor MT1 are consistent is determined. For example, whether they are both 3 or 1 is determined. If the color channel dimensions of the frame tensor FT and the model inputting tensor MT1 are consistent, the process proceeds to the step S224. If the color channel dimensions of the frame tensor FT and the model inputting tensor MT1 are inconsistent, the process proceeds to the step S223.

In the step S223, as shown in FIG. 2, a dimension transformation is executed on the frame tensor FT so that its color channel dimension matches that of the model input tensor MT1. This dimension transformation is executed using methods such as convolution.

In the step S224, as shown in FIG. 2, the frame tensor FT is input to the artificial intelligence model MD to obtain the inference result RS.

In the step S225, as shown in FIG. 2, the inference result RS is resized so that the size of the inference result RS is consistent with the size of the lighting effect device 130.

Next, in the step S231, as shown in FIG. 3, whether the squeeze flag FG1 is 1 is determined. If the squeeze flag FG1 is 1, the process proceeds to the step S232.

In the step S232, a dimension reduction is executed on the inference result RS. In this step, the inference result RS is squeezed to exclude data with a value of 1 in each dimension. This dimension reduction is executed while maintaining the same amount of data, speeding up the calculation and minimizing distortion.

Then, in the step S241, as shown in FIG. 3, whether the post-process merge flag FG2 is 1 is determined. If the post-process merge flag FG2 is 1, the process proceeds to the step S242; if the post-process merge flag FG2 is not 1, the process proceeds to the step S244.

In the steps S242 and S244, the data in the H-dimension and the W-dimension are obtained from the inference result RS.

Next, in the step S243, the inference result RS is merged. In this step, after obtaining the data in the H-dimension and the W-dimension from the inference result RS, the matrix data is merged through a concatenation operation to complete the lighting effect pattern LM.

Then, in the step S250, a lighting effect pattern LM is generated.

According to the above embodiments, the electronic device 100 utilizes the operating system kernel unit 150 to perform the initialization procedure PD1 and utilizes the CUDA 181 of the neural network processing unit 170 or the graphics processing unit 180 to perform the execution procedure PD2. In scenarios such as gaming and multimedia creation, the central processing unit 160 and the graphics processing unit 180 are nearly fully loaded, but the CUDA 181 of the neural network processing unit 170 and the CUDA 181 of the graphics processing unit 180 still have sufficient computational resources. Furthermore, the CUDA 181 of the neural network processing unit 170 and the CUDA 181 of the graphics processing unit 180 are particularly well-suited for artificial intelligence (AI) computing. Therefore, the present disclosure utilizes the computing resources of the CUDA 181 of the neural network processing unit 170 and the CUDA 181 of the graphics processing unit 180 to execute an artificial intelligence method for generating lighting effects. This allows for real-time calculation of the lighting effect pattern LM in response to rapid changes in the screen image FM.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. An artificial intelligence method for generating lighting effects, used to display a lighting effect pattern corresponding to a screen image on a lighting effect device, wherein the artificial intelligence method for generating the lighting effects comprises:
performing an initialization procedure to obtain a content and a dimension of a data format of a model inputting tensor and a model outputting tensor of an artificial intelligence model; and
performing an execution procedure to adjust a frame tensor of the screen image according to the content and the dimension of the data format of the model inputting tensor, and to adjust an inference result of the artificial intelligence model according to the content and the dimension of the data format of the model outputting tensor.

2. The artificial intelligence method for generating the lighting effects according to claim 1, wherein the initialization procedure comprises:
scanning the model inputting tensor;
determining whether the model inputting tensor has same color in a continuous space;
deeming that the model inputting tensor is in color channel-first data format, if the model inputting tensor has same color in the continuous space; and
deeming that the model inputting tensor is in color channel-last data format, if the model inputting tensor does not have same color in the continuous space.

3. The artificial intelligence method for generating the lighting effects according to claim 1, wherein the initialization procedure comprises:
scanning the model outputting tensor;
determining whether a first dimension or a last dimension of the model outputting tensor is 1;
setting a squeeze flag to 1, if the first dimension or the last dimension of the model outputting tensor is 1; and
setting the squeeze flag to 0, if the first dimension and the last dimension of the model outputting tensor are not 1.

4. The artificial intelligence method for generating the lighting effects according to claim 1, wherein the initialization procedure comprises:
scanning the model outputting tensor;
determining whether a color channel dimension of the model outputting tensor is less than 3; and
setting a post-process merge flag to 1, if the color channel dimension of the model outputting tensor is less than 3.

5. The artificial intelligence method for generating the lighting effects according to claim 1, wherein the execution procedure comprises:
obtaining a lighting effect width-height product of the lighting effect device and a screen image width-height product of the screen image;
determining whether the lighting effect width-height product is less or equal to the screen image width-height product;
determining whether the frame tensor and the model inputting tensor are both in the color channel-first data format or both in the color channel-last data format;
resizing the frame tensor, then transposing the frame tensor, if the lighting effect width-height product is less or equal to the screen image width-height product and the frame tensor and the model inputting tensor are not both in the color channel-first data format and are not both in the color channel-last data format; and
transposing the frame tensor, then resizing the frame tensor, if the lighting effect width-height product is larger than the screen image width-height product and the frame tensor and the model inputting tensor are not both in the color channel-first data format and are not both in the color channel-last data format.

6. The artificial intelligence method for generating the lighting effects according to claim 1, wherein the execution procedure comprises:
obtaining a color channel dimension of the frame tensor and a color channel dimension of the model inputting tensor;
determining whether the color channel dimension of the frame tensor is consistent with the color channel dimension of the model inputting tensor; and
performing a dimension conversion on the frame tensor, if the color channel dimension of the frame tensor is not consistent with the color channel dimension of the model inputting tensor.

7. The artificial intelligence method for generating the lighting effects according to claim 1, wherein in the step of performing the dimension conversion on the frame tensor, the dimension conversion is performed through convolution.

8. The artificial intelligence method for generating the lighting effects according to claim 1, wherein the execution procedure comprises:
determining whether a squeeze flag is 1, wherein when the squeeze flag is 1, a first dimension or a last dimension of the model outputting tensor is 1; and
executing a dimension reduction on the inference result of the artificial intelligence model, if the squeeze flag is 1.

9. The artificial intelligence method for generating the lighting effects according to claim 1, wherein in the step of executing the dimension reduction on the inference result of the artificial intelligence model, data with a value of 1 in each dimension is excluded.

10. The artificial intelligence method for generating the lighting effects according to claim 1, wherein the execution procedure comprises:
determining whether a post-process merge flag is 1, when the post-process merge flag is 1, a color channel dimension of the model outputting tensor is less than 3; and
merging the inference result of the artificial intelligence model, if the post-process merge flag is 1.

11. An electronic device, comprising:
a display unit, used to display a screen image;
a lighting effect device, used to display a lighting effect pattern corresponding to the screen image;
an operating system kernel unit, connected to the display unit and the lighting effect device;
a neural network processing unit (NPU), connected to the operating system kernel unit; and
a graphic process unit (GPU), connected to the operating system kernel unit, wherein the graphic process unit includes:
a Compute Unified Device Architecture (CUDA), wherein the electronic device is loaded with a program to execute an artificial intelligence method for generating lighting effects, and the artificial intelligence method for generating the lighting effects comprises:
performing, by the operating system kernel unit, an initialization procedure to obtain a content and a dimension of a data format of a model inputting tensor and a model outputting tensor of an artificial intelligence model; and
performing, by the CUDA of the neural network processing unit or the graphic process unit, an execution procedure, to adjust a frame tensor of the screen image according to the content and the dimension of the data format of the model inputting tensor, and to adjust an inference result of the artificial intelligence model according to the content and the dimension of the data format of the model outputting tensor.

12. The electronic device according to claim 11, wherein the initialization procedure comprises:
scanning the model inputting tensor;
determining whether the model inputting tensor has same color in a continuous space;
deeming that the model inputting tensor is in color channel-first data format, if the model inputting tensor has same color in the continuous space; and
deeming that the model inputting tensor is in color channel-last data format, if the model inputting tensor does not have same color in the continuous space.

13. The electronic device according to claim 11, wherein the initialization procedure comprises:
scanning the model outputting tensor;
determining whether a first dimension or a last dimension of the model outputting tensor are 1;
setting a squeeze flag to 1, if the first dimension or the last dimension of the model outputting tensor is 1; and
setting the squeeze flag to 0, if the first dimension and the last dimension of the model outputting tensor are not 1.

14. The electronic device according to claim 11, wherein the initialization procedure comprises:
scanning the model outputting tensor;
determining whether a color channel dimension of the model outputting tensor is less than 3; and
setting a post-process merge flag to 1, if the color channel dimension of the model outputting tensor is less than 3.

15. The electronic device according to claim 11, wherein the execution procedure comprises:
obtaining a lighting effect width-height product of the lighting effect device and a screen image width-height product of the screen image;
determining whether the lighting effect width-height product is less or equal to the screen image width-height product;
determining whether the frame tensor and the model inputting tensor are both in the color channel-first data format or both in the color channel-last data format;
resizing the frame tensor, then transposing the frame tensor, if the lighting effect width-height product is less or equal to the screen image width-height product and the frame tensor and the model inputting tensor are not both in the color channel-first data format and are not both in the color channel-last data format; and
transposing the frame tensor, then resizing the frame tensor, if the lighting effect width-height product is larger than the screen image width-height product and the frame tensor and the model inputting tensor are not both in the color channel-first data format and are not both in the color channel-last data format.

16. The electronic device according to claim 11, wherein the execution procedure comprises:
obtaining a color channel dimension of the frame tensor and a color channel dimension of the model inputting tensor;
determining whether the color channel dimension of the frame tensor is consistent with the color channel dimension of the model inputting tensor; and
performing a dimension conversion on the frame tensor, if the color channel dimension of the frame tensor is not consistent with the color channel dimension of the model inputting tensor.

17. The electronic device according to claim 16, wherein during performing the dimension conversion on the frame tensor, the dimension conversion is performed through convolution.

18. The electronic device according to claim 11, wherein the execution procedure comprises:
determining whether a squeeze flag is 1, wherein when the squeeze flag is 1, a first dimension or a last dimension of the model outputting tensor is 1; and
executing a dimension reduction on the inference result of the artificial intelligence model, if the squeeze flag is 1.

19. The electronic device according to claim 11, wherein during executing the dimension reduction on the inference result of the artificial intelligence model, data with a value of 1 in each dimension is excluded.

20. The electronic device according to claim 11, wherein the execution procedure comprises:
determining whether a post-process merge flag is 1, when the post-process merge flag is 1, a color channel dimension of the model outputting tensor is less than 3; and
merging the inference result of the artificial intelligence model, if the post-process merge flag is 1.
